(19) United States
(12) Patent Application Publication
(10) Pub. No.: US 2025/0160044 A1
(43) Pub. Date: May 15, 2025

(54) GROUP III NITRIDE VERTICAL PHOTOCONDUCTIVE SEMICONDUCTOR SWITCH

(71) Applicant: SixPoint Materials, Inc., Buellton, CA (US)

(72) Inventor: Tadao Hashimoto, Santa Barbara, CA (US)

(21) Appl. No.: 18/716,922

(22) PCT Filed: May 14, 2024
(86) PCT No.: PCT/US2024/029179

§ 371 Date: Jun. 5, 2024

Related U.S. Application Data
(60) Provisional application No. 63/466,344, filed on May 14, 2023.

(51) Int. Cl. H10F 77/124; H10F 30/22; H10F 77/20

(52) U.S. Cl. CPC H10F 77/1243; H10F 30/22; H10F 77/1246; H10F 77/241

(57) ABSTRACT

The present invention discloses a vertical photoconductive semiconductor switch (PCSS) made of group III nitride material. The vertical PCSS is made of a plate of a semi-insulating group III nitride crystal such as GaN, AlN, and BN. The vertical PCSS has an electrically conductive region on the top surface, which acts as a window for the photo irradiation. There is a top electrode connected to the electrically conductive region. The shortest distance from the edge of the plate to the boundary of the electrically conductive region and the boundary of the top electrode is preferably larger than the thickness of the plate. The Vertical PCSS also has an electrode on the bottom surface of the plate.

### CROSS REFERENCE TO RELATED APPLICATIONS

This patent application claims the benefits of priority to U.S. Pat. App. 63/466,344 entitled “Group III Nitride Vertical Photoconductive Semiconductor Switch”, filed May 14, 2023 and naming Tadao Hashimoto as inventor, the contents of which are incorporated by reference herein.

This application is related to the following patent applications:
PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.0129-WO-01 (2005-339-1);
U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);
U.S. Utility Patent Application Ser. No. 60/973,602, filed on Sep. 19, 2007, by Tadao Hashimoto and Shuji Nakamura, entitled “GALLIUM NITRIDE BULK CRYSTALS AND THEIR GROWTH METHOD,” attorneys docket number 30794.244-US-P1 (2007-809-1);
U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys docket number 30794.253-US-U1 (2007-774-2);
U.S. Utility patent application Ser. No. 12/392,960, filed on Feb. 25, 2009, by Tadao Hashimoto, Edward Letts, Masanori Ikari, entitled “METHOD FOR PRODUCING GROUP III-NITRIDE WAFERS AND GROUP III-NITRIDE WAFERS,” attorneys docket number SIXPOI-003US;
U.S. Utility patent application Ser. No. 12/455,760, filed on Jun. 4, 2009, by Edward Letts, Tadao Hashimoto, Masanori Ikari, entitled “METHODS FOR PRODUCING IMPROVED CRYSTALLINITY GROUP III-NITRIDE CRYSTALS FROM INITIAL GROUP III-NITRIDE SEED BY AMMONOTHERMAL GROWTH,” attorneys docket number SIXPOI-002US;
U.S. Utility patent application Ser. No. 12/455,683, filed on Jun. 4, 2009, by Tadao Hashimoto, Edward Letts, Masanori Ikari, entitled “HIGH-PRESSURE VESSEL FOR GROWING GROUP III NITRIDE CRYSTALS AND METHOD OF GROWING GROUP III NITRIDE CRYSTALS USING HIGH-PRESSURE VESSEL AND GROUP III NITRIDE CRYSTAL,” attorneys docket number SIXPOI-005US;
U.S. Utility patent application Ser. No. 12/455,181, filed on Jun. 12, 2009, by Tadao Hashimoto, Masanori Ikari, Edward Letts, entitled “METHOD FOR TESTING III-NITRIDE WAFERS AND III-NITRIDE WAFERS WITH TEST DATA,” attorneys docket number SIXPOI-001US;
U.S. Utility patent application Ser. No. 12/580,849, filed on Oct. 16, 2009, by Tadao Hashimoto, Masanori Ikari, Edward Letts, entitled “REACTOR DESIGN FOR GROWING GROUP III NITRIDE CRYSTALS AND METHOD OF GROWING GROUP III NITRIDE CRYSTALS,” attorneys docket number SIXPOI-004US;
U.S. Utility patent application Ser. No. 13/781,509, filed on Feb. 28, 2013, by Tadao Hashimoto, entitled “COMPOSITE SUBSTRATE OF GALLIUM NITRIDE AND METAL OXIDE,” attorneys docket number SIXPOI-012US;
U.S. Utility patent application Ser. No. 13/781,543, filed on Feb. 28, 2013, by Tadao Hashimoto, Edward Letts, Sierra Hoff entitled “A BISMUTH-DOPED SEMI-INSULATING GROUP III NITRIDE WAFER,” attorneys docket number SIXPOI-013US;
U.S. Utility patent application Ser. No. 13/833,443, filed on Mar. 15, 2013, by Tadao Hashimoto, Edward Letts, Sierra Hoff entitled “METHOD OF GROWING GROUP III NITRIDE CRYSTALS,” attorneys docket number SIXPOI-014US1;
U.S. Utility patent application Ser. No. 13/834,015, filed on Mar. 15, 2013, by Tadao Hashimoto, Edward Letts, Sierra Hoff entitled “METHOD OF GROWING GROUP III NITRIDE CRYSTALS,” attorneys docket number SIXPOI-014US2;
U.S. Utility patent application Ser. No. 13/834,871, filed on Mar. 15, 2013, by Tadao Hashimoto, Edward Letts, Sierra Hoff entitled “GROUP III NITRIDE WAFER AND ITS PRODUCTION METHOD,” attorneys docket number SIXPOI-015US1;
U.S. Utility patent application Ser. No. 13/835,636, filed on Mar. 15, 2013, by Tadao Hashimoto, Edward Letts, Sierra Hoff entitled “GROUP III NITRIDE WAFER AND ITS PRODUCTION METHOD,” attorneys docket number SIXPOI-015US2;
U.S. Utility patent application Ser. No. 13/798,530, filed on Mar. 13, 2013, by Tadao Hashimoto, entitled “GROUP III NITRIDE WAFERS AND FABRICATION METHOD AND TESTING METHOD,” attorneys docket number SIXPOI-016US;
U.S. Utility patent application Ser. No. 14/329,730, filed on Jul. 23, 2014, by Tadao Hashimoto, entitled “ELECTRONIC DEVICE USING GROUP III NITRIDE SEMICONDUCTOR AND ITS FABRICATION METHOD,” attorneys docket number SIXPOI-017US;
which applications are incorporated by reference herein in their entirety as if put forth in full below.

This invention was made with government support under contract DE-AR0001562 awarded by the U.S. Department of Energy, ARPA-E. The government has certain rights in the invention.

### BACKGROUND

### Field of the Invention

The invention relates to a semiconductor electronic device primarily used for high-voltage semiconductor switch. More specifically, the invention is on a photoconductive semiconductor switch using group III nitride semiconductor.

### Description of the Existing Technology

(Note: This patent application refers several publications and patents as indicated with numbers within brackets, e.g., [x]. A list of these publications and patents can be found in the section entitled “References.”)

Wide bandgap group III nitride such as gallium nitride (GaN), aluminum nitride (AlN), and boron nitride (BN) are the key semiconductor material for various high-power electronic devices such as power switching devices. Although metal oxide semiconductor field effect transistors (MOSFETs) are common switching devices, state-of-the-art GaN MOSFET is unable to handle medium voltage to high voltage range. Also, some applications require complete isolation of control signal from the load circuit. For such purposes, a photo triggered device is ideal because the optical signal is not disturbed by the noise in the load circuit and vice versa.

A photoconductive semiconductor switch (PCSS) is a switching device with two electrodes formed on a semi-insulating semiconductor material. A horizontal type PCSS has two electrodes on the same surface, and light is irradiated into the gap between the electrodes. Carriers are generated by the irradiated photons, and the current flows near the surface of the material. A GaN PCSS of this type with a few kV capacity is demonstrated at this time.

A horizontal PCSS configuration is very limited in total power that it can handle. To increase the blocking voltage, the distance between its two electrodes is increased. Also, to increase the current, the width of the electrode is increased. However, since the current flows near the surface of the material, an increase in material thickness does not increase the electric current. Therefore, at a given blocking voltage, the current capacity increases only one dimensionally, by the width of the electrode.

### SUMMARY OF THE INVENTION

To increase the power handling capability over a horizontal PCSS as discussed above, a vertical PCSS is provided herein. A vertical PCSS has two electrodes, one on each major side of a group III nitride crystal. The blocking voltage is determined by the thickness of the crystal, and the current capacity is determined by the area of the device. Therefore, the current capacity increases two dimensionally by the size of the device. However, unlike the horizontal PCSS, the vertical PCSS has limited access of light. To maximize the merit of vertical configuration, a proper device design is required.

The present invention discloses a vertical PCSS made of group III nitride material. The vertical PCSS is made of a plate of a semi-insulating group III nitride crystal such as GaN, AlN, and BN. The vertical PCSS has an electrically conductive region on the top surface, which is preferably crystalline and which acts as a window for the photo irradiation. There is a top electrode connected to the electrically conductive region. The top electrode preferably surrounds the conductive region, and at least a portion of the top electrode will typically overlie the conductive region. The distance (d) between a plate edge and adjacent top electrode or adjacent conductive region is preferably greater than the thickness of the plate in order to reduce or eliminate electrical breakdown of the switch (e.g. caused by surface breakdown in the electrically conductive region). Preferably, the shortest distance from any edge of the plate to the adjacent common boundary of the electrically conductive region and the top electrode is larger than the thickness of the plate. In other words, preferably the distance (d) is the shorter of the two distances measured between an edge of the plate and either the edge of the top electrode or the edge of the adjacent electrically conductive region. In one instance, both the shortest distance between any plate edge and its adjacent top electrode and the shortest distance between any plate edge and its adjacent conductive region are greater than the thickness of the plate. The vertical PCSS also has an electrode on the bottom surface of the plate.

The semi-insulating group III nitride crystal is preferably grown in supercritical ammonia using manganese as a dopant. The crystal is shaped into a plate shape with exposed group III face and nitrogen face. The electrically conductive region is formed on one side of the plate, preferably on the nitrogen face, preferably by ion implantation of a donor element. The top electrode is formed on the electrically conductive region. The shape and the configuration of the top electrode are designed so that a large enough area of the electrically conductive region is exposed for light irradiation. The bottom electrode is formed on the opposite side of the plate.

### BRIEF DESCRIPTION OF THE DRAWINGS

Referring now to the drawings in which like reference numbers represent corresponding parts throughout:

FIG. 1 is a perspective drawing that illustrates an example of a vertical PCSS chip of this invention.

In the figure each number and character represents the following:
11. A plate of a semi-insulating group III nitride crystal
12. A bottom electrode
13. An electrically conductive region
14. A top electrode
d. The shortest distance from the edge of the plate to the common boundary of the electrically conductive area and the top electrode.
t. The thickness of the plate measured along an edge.

FIG. 2 illustrates a cross-section of the vertical PCSS along 2-2 indicated in FIG. 1.

In the figure each number and character represents the following:
21. A plate of a semi-insulating group III nitride crystal
22. A bottom electrode
23. An electrically conductive region
23A. The lower edge of the electrically conductive region
24. A top electrode
d. The shortest distance from the edge of the plate to the common boundary of the electrically conductive area and the top electrode.
t. The thickness of the plate.

FIG. 3 illustrates a top view of the vertical PCSS in FIG. 1.

In the figure each number and character represents the following:
31. A plate of a semi-insulating group III nitride crystal
33. An electrically conductive region
34. A top electrode
d. The shortest distance from the edge of the plate to the common boundary of the electrically conductive area and the top electrode.

### DETAILED DESCRIPTION OF THE INVENTION

A vertical PCSS potentially switches a high voltage of at least about 1 kV, at least about 10 kV, and at least 100 kV and over. However, to handle such a high voltage and to increase current rating of the device, it is important to increase the quantum efficiency of the device. There are two kinds of quantum efficiency, internal quantum efficiency and external quantum efficiency.

Internal quantum efficiency measures how efficiently the device converts photons that entered the device into electron-hole pairs. The internal quantum efficiency is determined by material properties such as defect densities and doping concentrations of impurities.

On the other hand, external quantum efficiency is obtained by multiplying the internal quantum efficiency by external factors such as the transmission of light into the material and electrical efficiency of the device. To maximize the device efficiency, both internal and external quantum efficiency can be maximized in the device disclosed herein.

In this invention, the internal quantum efficiency is maximized by using a group III nitride crystal with low dislocation density, such as one grown by the ammonothermal method using supercritical ammonia. As explained in the cross-referenced patents mentioned previously, the ammonothermal method can grow GaN crystals with dislocation density lower than 5×10⁵ cm⁻², which is about one order of magnitude lower than GaN crystals grown by hydride vapor phase epitaxy (HVPE).

To achieve semi-insulating property, manganese for example is added as a carrier killer. The manganese concentration is higher than 5×10¹⁸ cm⁻³ in the GaN crystal prior to forming the PCSS to achieve sufficient resistivity (e.g. higher than 10¹⁰ Ohm cm).

The external quantum efficiency is maximized by eliminating the electrode (typically a metal such as a stack of Ni/Au or Ti/Al/Ni/Au) as much as possible from the optical path. The optical power blocked by the electrode is preferably less than 10% of the total optical power irradiated to the device. The light source can be either a focused light or laser light such as focused white light from white LEDs, focused blue light from blue LEDs, focused light of Kr lamp, focused light from Nd:YAG lasers. The type of the triggering light is selected to maximize the internal and external quantum efficiency. For example, by matching the absorption peak of the Mn—GaN to the laser wavelength, one can maximize the internal quantum efficiency. Also, shining light a source with multiple wavelengths that match a few absorption peaks of Mn—GaN, like mid-gap peak, conduction band-tail peak and band-edge wavelength will further potentially increase the internal quantum efficiency.

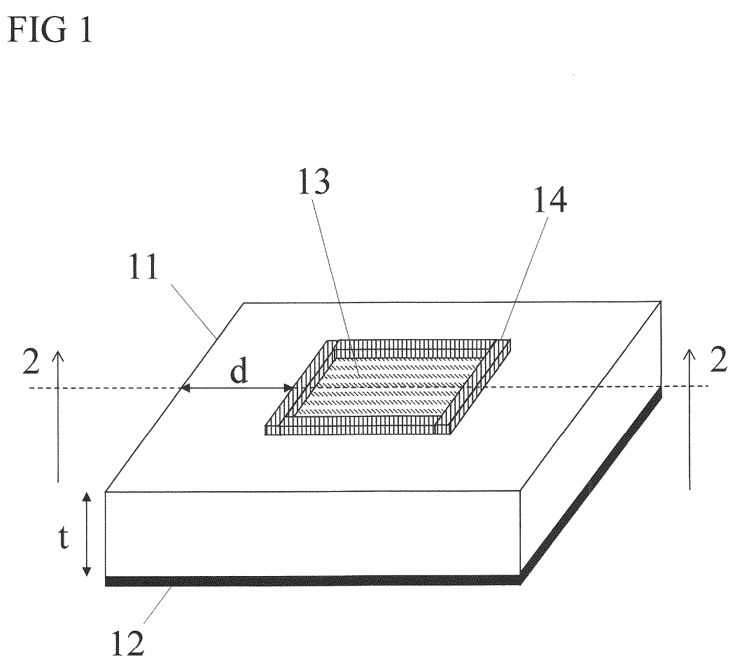

To ensure uniform distribution of the current along the vertical direction, the PCSS in this invention has an electrically conductive region which spreads the current over the entire photo-irradiated area. FIG. 1 shows a schematic of one vertical PCSS in this invention. A plate of group III nitride crystal 11 has an electrically conductive region 13 on the top surface of the plate. The top surface facing the light source is preferably the nitrogen face of the crystal because the polarity of the spontaneous polarization helps to increase the blocking voltage. A top electrode 14, which is electrically connected to the electrically conductive region, is formed on or near the edge of the electrically conductive region. As depicted in FIG. 1, the top electrode may surround the conductive region on all of its sides, leaving a portion of the region exposed to the light used to trigger the switch. A bottom electrode 12 is of e.g. a stack of Ni/Au or Ti/Al/Ni/Au formed on the back (opposite) side of the plate. The backside of the plate is preferably group III face of the crystal.

To reduce or avoid breakdown of the device via surface breakdown under high voltage, the shortest distance from the edge of the plate 11 to the boundary of the electrically conductive area 13 or the boundary of the top electrode 14, d, is preferably larger than the thickness of the plate 11, t. In FIG. 1, the boundary of the electrically conductive area 13 and the boundary of the top electrode 14 are at the same position. However, if the boundaries do not match, the shorter distance from the edge of the plate 11 to the boundary of either the electrically conductive area 13 or the top electrode 14 should be larger than the thickness of the plate 11. The electrode may therefore reside partially on the electrically conductive area and partially on the adjacent non-conductive area of the plate as long as the electrode provides sufficiently uniform electrical conduction and voltage for switch operation.

A top electrode may comprise a material that is transparent or mostly transparent to one or more of the wavelengths of light used to trigger the switch. For instance, the top electrode may be formed of indium tin oxide (ITO).

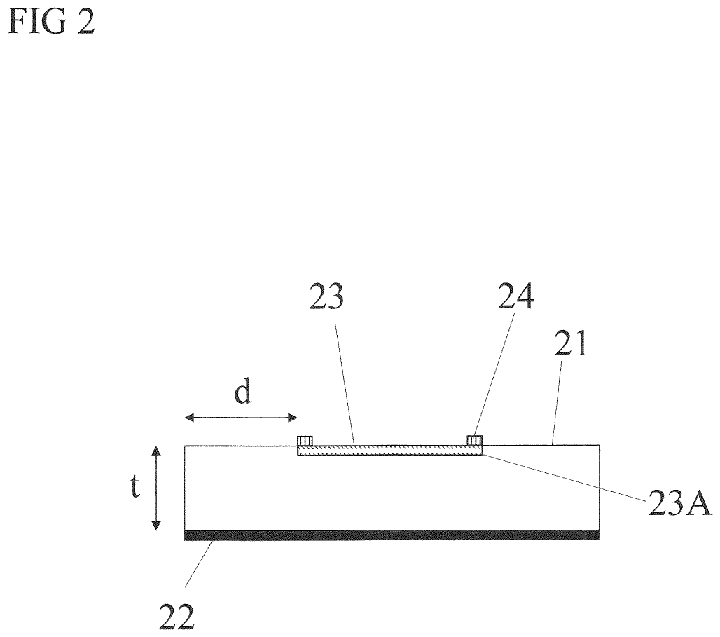

FIG. 2 shows the cross-section of the PCSS along 2-2 shown in FIG. 1. The electrically conductive region is formed inside the plate. It is preferable to use ion implantation of donors such as silicon and oxygen to form the electrically conductive region. The concentration of the donor impurities is higher than the concentration of the manganese at the top surface so that the ion-implanted area becomes n-type and electrically conductive. The depth of the electrically conductive region can be thin as long as the electrically conductive region spreads the current over the photo-irradiated area. The thickness of the electrically conductive region can be less than 1 micron.

Since commonly-available ion implantation equipment spreads the donor impurities in both horizontal and vertical directions, the donor concentration gradually decreases along horizontal (lateral) and vertical (depth) direction in the electrically conductive area to a position that the plate changes from semi-insulating to n-type. This helps mitigate the concentration of the electric field at the lower edge of the electrically conductive region 23A, thus increasing the maximum breakdown voltage of the device.

Another way of forming the conductive region in a plate is to etch a portion of the top surface of the plate followed by deposition of electrically conductive material like n-GaN or ITO (indium tin oxide). The conductive region can absorb light as long as it generates free-electrons and transfers them into the plate. In this manner, the plate may be the same crystalline material as the electrically conductive material or may be a different material. In one instance, the plate is semi-insulating GaN as described above and the electrically conductive material is n-GaN that lacks the carrier killer of the semi-insulating GaN. In another instance, the plate is semi-insulating group III nitride such as Mn-doped GaN or another semi-insulating material such as Mn-doped AlGaN.

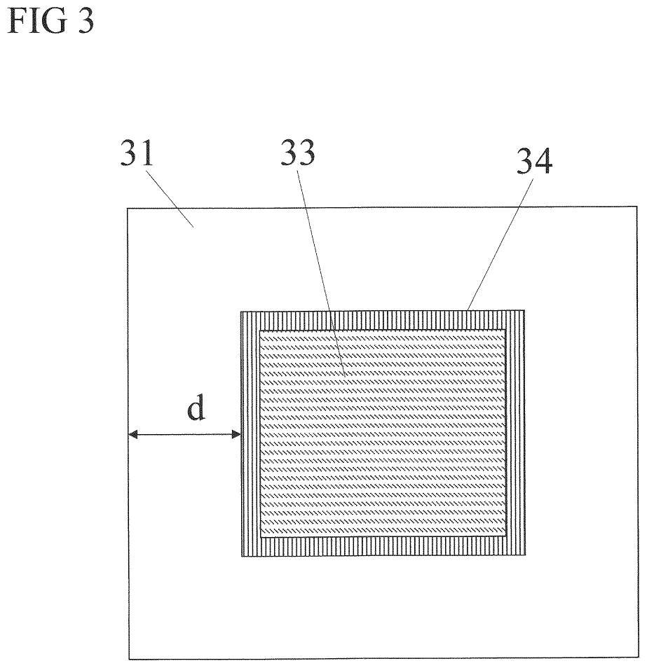

FIG. 3 shows the top view of the PCSS in FIG. 1. The top electrode forms a window area on the electrically conductive region that lies between all of the portions of the top electrode, so that the irradiated light is not blocked by the top electrode.

High voltage is applied between the top electrode and the bottom electrode. Under the biased condition, the top electrode and the electrically conductive region have the same potential, thus the generated carriers on the photo-irradiated area will be transported vertically towards the bottom electrode. In other words, the electrically conductive region spreads the current over the photo-irradiated area.

In addition, by avoiding the direct light irradiation on the metal electrode, breakdown of the device at the edge of the electrode is prevented through mitigation of metal migration into the semiconductor material. It is therefore preferable to have a laser beam or a focused beam generated by another light source whose spot on the electrically conductive region has an area smaller than or about equal to the exposed area of the electrically conductive region to avoid irradiating the electrode. The electrode may also be positioned adjacent to the electrically conductive region as long as the electrode and electrically conductive region conduct sufficiently that voltage is essentially stable.

Since the electrically conductive region acts as a window for photo irradiation, the device can optionally have an anti-reflective coating such as a stack of dielectric layers of Al₂O₃ and SiO₂ on the electrically conductive region.

Consequently, examples of the invention as described herein include but are not limited to the following:
1. A photoconductive semiconductor switch triggered by irradiation of focused light or laser light comprising
   (a) a plate of a semi-insulating group III nitride crystal having a top surface and a bottom surface,
   (b) a bottom electrode on the bottom surface;
   (c) a photo-active electrically conductive region in the plate and exposed to the top surface, and
   (d) a top electrode electrically connected to the electrically conductive region.
2. The photoconductive semiconductor switch of paragraph 1, wherein the top electrode surrounds the photo-active electrically conductive region.
3. The photoconductive semiconductor switch of paragraph 1 or paragraph 2, wherein the top electrode covers the photo-active electrically conductive region.
4. The photoconductive semiconductor switch of any one of paragraphs 1-3, wherein the photo-active electrically conductive region is crystalline.
5. The photoconductive semiconductor switch of paragraph 4, wherein the electrically conductive region comprises said semi-insulating group III nitride crystal.
6. The photoconductive semiconductor switch of any one of paragraphs 1-5, wherein the photo-active electrically conductive region is n-type and contains a donor impurity.
7. The photoconductive semiconductor switch of any one of paragraphs 1-6, wherein said group III nitride crystal contains manganese, the manganese concentration on the bottom surface of the plate is greater than 5×10¹⁸ cm⁻³, and the concentration of the donor impurity in the photo-active electrically conductive region is higher than the concentration of manganese on the top surface of the plate.
8. The photoconductive semiconductor switch of paragraph 6 or paragraph 7, wherein the donor impurity comprises silicon.
9. The photoconductive semiconductor switch of any one of paragraphs 1-8, wherein a first shortest distance from an edge of the top surface to an adjacent boundary of the photo-active electrically conductive region is more than a thickness of the plate.
10. The photoconductive semiconductor switch of any one of paragraphs 1-9, wherein a second shortest distance from the edge of the top surface to the top electrode is more than the thickness of the plate.
11. The photoconductive semiconductor switch of any one of paragraphs 1-10, wherein the top electrode has a surface area on the photo-active electrically conductive region that is less than 10% of a surface area of the photo-active electrically conductive region.
12. The photoconductive semiconductor switch of any one of paragraphs 1-11, wherein the top surface is a nitrogen face of the semi-insulating group III nitride crystal and the bottom surface is a group III face of the semi-insulating group III nitride crystal.
13. The photoconductive semiconductor switch of any one of paragraphs 1-12, wherein the semi-insulating group III nitride is GaN.
14. The photoconductive semiconductor switch of paragraph 13, wherein a dislocation density of the GaN is less than 5×10⁵ cm⁻².
15. A switch assembly comprising a photoconductive semiconductor switch of any paragraph above and a light source positioned to irradiate and activate the electrically conductive area.
16. A photoconductive semiconductor switch triggered by irradiation of focused light or laser light comprising
   (a) a plate of a semi-insulating group III nitride crystal having a top surface and a bottom surface,
   (b) a bottom electrode on the bottom surface;
   (c) a photo-active electrically conductive region inside the plate and exposed to the top surface,
   (d) a top electrode electrically connected to the electrically conductive region,
   wherein a first shortest distance from an edge of the top surface to an adjacent boundary of the electrically conductive region is more than a thickness of the plate, a second shortest distance from the edge of the top surface to the top electrode is more than the thickness of the plate, and the top electrode has a surface area on the electrically conductive region that is less than 10% of a surface area of the electrically conductive region.
17. The photoconductive semiconductor switch of paragraph 16, wherein the electrically conductive region is n-type and contains a donor impurity.
18. The photoconductive semiconductor switch of paragraph 17, wherein the plate contains manganese, the manganese concentration on the bottom surface is higher than 5×10¹⁸ cm⁻³, and the concentration of the donor impurity in the electrically conductive region is higher than the concentration of manganese on the top surface.
19. The photoconductive semiconductor switch of paragraph 18, wherein the donor impurity comprises silicon.
20. The photoconductive semiconductor switch of paragraph 19, wherein the top surface is a nitrogen face of the semi-insulating group III nitride crystal and the bottom surface is a group III face of the semi-insulating group III nitride crystal.
21. The photoconductive semiconductor switch of paragraph 20, wherein the semi-insulating group III nitride is GaN.
22. The photoconductive semiconductor switch of paragraph 21, wherein the dislocation density of the GaN is less than 5×10⁵ cm⁻².
23. The photoconductive semiconductor switch of paragraph 17, wherein the donor impurity comprises silicon.
24. The photoconductive semiconductor switch of paragraph 18, wherein the top surface is a nitrogen face of the semi-insulating group III nitride crystal and the bottom surface is a group III face of the semi-insulating group III nitride crystal.
25. The photoconductive semiconductor switch of paragraph 16, wherein the semi-insulating group III nitride is GaN.
26. The photoconductive semiconductor switch of paragraph 18, wherein the semi-insulating group III nitride is GaN.
27. The photoconductive semiconductor switch of paragraph 25, wherein the dislocation density of the GaN is less than 5×10⁵ cm⁻².
28. The photoconductive semiconductor switch of paragraph 26, wherein the dislocation density of the GaN is less than 5×10⁵ cm⁻².
29. A switch assembly comprising a photoconductive semiconductor switch of paragraph 16 and a light source positioned to irradiate and activate the electrically conductive area.
30. A switch assembly comprising a photoconductive semiconductor switch of paragraph 17 and a light source positioned to irradiate and activate the electrically conductive area.
31. A switch assembly comprising a photoconductive semiconductor switch of paragraph 22 and a light source positioned to irradiate and activate the electrically conductive area.
32. A switch assembly comprising a photoconductive semiconductor switch of paragraph 24 and a light source positioned to irradiate and activate the electrically conductive area.
33. A switch assembly comprising a photoconductive semiconductor switch of paragraph 25 and a light source positioned to irradiate and activate the electrically conductive area.
34. A switch assembly comprising a photoconductive semiconductor switch of paragraph 26 and a light source positioned to irradiate and activate the electrically conductive area.
35. A switch assembly comprising a photoconductive semiconductor switch of paragraph 27 and a light source positioned to irradiate and activate the electrically conductive area.
36. A switch assembly comprising a photoconductive semiconductor switch of paragraph 28 and a light source positioned to irradiate and activate the electrically conductive area.

### Example 1

A bulk crystal of manganese doped GaN (Mn—GaN) is grown by the near-equilibrium ammonothermal method. A bulk crystal of Mn—GaN is grown on a nitrogen surface of a c-plane GaN seed crystal. The grown bulk crystal of Mn—GaN is diced into 15×15 mm plate with thickness of 3.2 mm. The top and the bottom surfaces are ground, lapped, mechanically polished, and chemomechanically polished (CMP) to form 15×15×3 mm plate of Mn—GaN crystal. The Mn concentrations on the Ga face and the N face are 5.1×10¹⁸ cm⁻³ and 3.8×10¹⁸ cm⁻³.

The N face of the plate is implanted with e.g. silicon using a metal mask covering the edge of the plate to form an electrically conductive region at the center of the N face. The ion energy and dosages are first 10 keV and 2×10¹³ cm⁻² and subsequently 65 keV and 5×10¹³ cm⁻³, respectively. This two-step ion implantation creates the electrically conductive region of about 0.1 microns in depth with peak silicon concentration about 1×10¹⁹ cm⁻³. The electrically conductive region becomes n-type GaN.

Then, a top electrode consisting of e.g. Ti/Al/Ti/Au is formed using a conventional semiconductor patterning process. Similarly, a bottom electrode of Ti/Al/Ti/Au is formed. The bottom electrode does not need patterning.

### Example 2

The PCSS fabricated in Example 1 is biased with 50 kV, and 5 mJ of Nd:YAG laser is irradiated on the electrically conductive region. The laser pulse width is about 10 ns. Upon laser irradiation, the PCSS turns on and a pulsed current flows. The peak current is over 100 A and the current width is about 50 ns. The power capability is 5 MW.

### Possible Modifications

Although the preferred embodiment describes usage of GaN crystal, the other group III nitride crystal such as AlN and BN can also be used.

Although the preferred embodiment describes usage of ion implantation of donor to create the electrically conductive region, other methods such as using selective MOCVD regrowth after etching can also be used.

Although the preferred embodiment describes silicon as the donor impurity, other donors such as oxygen can also be used.

Although the preferred embodiment describes square shape of the device, the electrically conductive region, and the top electrode, other shapes such as circle, rectangle, and hexagon can be used.

Although the preferred embodiment describes Ti/Al/Ti/Au as contact material, other combination of metals such as Ni/Au, Ti/Au, W/Au, and Pd/Au can be used. If necessary an appropriate interlayer such as Cr can be used to ensure sufficient bonding of each layer.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1-15. (canceled)

16. A photoconductive semiconductor switch triggered by irradiation of focused light or laser light comprising
(a) a plate of a semi-insulating group III nitride crystal having a top surface and a bottom surface,
(b) a bottom electrode on the bottom surface;
(c) a photo-active electrically conductive region inside the plate and exposed to the top surface,
(d) a top electrode electrically connected to the electrically conductive region,
wherein a first shortest distance from an edge of the top surface to an adjacent boundary of the electrically conductive region is more than a thickness of the plate, a second shortest distance from the edge of the top surface to the top electrode is more than the thickness of the plate, and the top electrode has a surface area on the electrically conductive region that is less than 10% of a surface area of the electrically conductive region.

17. The photoconductive semiconductor switch of claim 16, wherein the electrically conductive region is n-type and contains a donor impurity.

18. The photoconductive semiconductor switch of claim 17, wherein the plate contains manganese, the manganese concentration on the bottom surface is higher than 5×10¹⁸ cm⁻³, and the concentration of the donor impurity in the electrically conductive region is higher than the concentration of manganese on the top surface.

19. The photoconductive semiconductor switch of claim 18, wherein the donor impurity comprises silicon.

20. The photoconductive semiconductor switch of claim 19, wherein the top surface is a nitrogen face of the semi-insulating group III nitride crystal and the bottom surface is a group III face of the semi-insulating group III nitride crystal.

21. The photoconductive semiconductor switch of claim 20, wherein the semi-insulating group III nitride is GaN.

22. The photoconductive semiconductor switch of claim 21, wherein the dislocation density of the GaN is less than 5×10⁵ cm⁻².

23. The photoconductive semiconductor switch of claim 17, wherein the donor impurity comprises silicon.

24. The photoconductive semiconductor switch of claim 18, wherein the top surface is a nitrogen face of the semi-insulating group III nitride crystal and the bottom surface is a group III face of the semi-insulating group III nitride crystal.

25. The photoconductive semiconductor switch of claim 16, wherein the semi-insulating group III nitride is GaN.

26. The photoconductive semiconductor switch of claim 18, wherein the semi-insulating group III nitride is GaN.

27. The photoconductive semiconductor switch of claim 25, wherein the dislocation density of the GaN is less than 5×10⁵ cm⁻².

28. The photoconductive semiconductor switch of claim 26, wherein the dislocation density of the GaN is less than 5×10⁵ cm⁻².

29. A switch assembly comprising a photoconductive semiconductor switch of claim 16 and a light source positioned to irradiate and activate the electrically conductive area.

30. A switch assembly comprising a photoconductive semiconductor switch of claim 17 and a light source positioned to irradiate and activate the electrically conductive area.

31. A switch assembly comprising a photoconductive semiconductor switch of claim 22 and a light source positioned to irradiate and activate the electrically conductive area.

32. A switch assembly comprising a photoconductive semiconductor switch of claim 24 and a light source positioned to irradiate and activate the electrically conductive area.

33. A switch assembly comprising a photoconductive semiconductor switch of claim 25 and a light source positioned to irradiate and activate the electrically conductive area.

34. A switch assembly comprising a photoconductive semiconductor switch of claim 26 and a light source positioned to irradiate and activate the electrically conductive area.

35. A switch assembly comprising a photoconductive semiconductor switch of claim 27 and a light source positioned to irradiate and activate the electrically conductive area.

36. A switch assembly comprising a photoconductive semiconductor switch of claim 28 and a light source positioned to irradiate and activate the electrically conductive area.
